(19) United States
(12) Patent Application Publication
(10) Pub. No.: US 2023/0335563 A1
(43) Pub. Date: Oct. 19, 2023

(54) ELECTRONIC DEVICE

(71) Applicant: Innolux Corporation, Miaoli County (TW)

(72) Inventor: Chia-Ping Tseng, Miaoli County (TW)

(73) Assignee: Innolux Corporation, Miaoli County (TW)

(21) Appl. No.: 18/183,955

(22) Filed: Mar. 15, 2023

Related U.S. Application Data
(60) Provisional application No. 63/330,319, filed on Apr. 13, 2022.

(30) Foreign Application Priority Data
Jan. 3, 2023 (CN) 202310002856.1

(51) Int. Cl. H01L 27/12; H01L 23/00; H01L 25/18; H01L 25/16

(52) U.S. Cl. CPC H01L 27/124; H01L 24/13; H01L 24/16; H01L 25/18; H01L 25/16; H01L 2924/12034; H01L 2924/1426; H01L 2224/05548; H01L 2224/05567; H01L 2224/13021; H01L 2224/13144; H01L 2224/13155; H01L 2924/0132; H01L 2224/13582; H01L 2224/1357; H01L 27/1225; H01L 27/1255; H01L 2224/16145

(57) ABSTRACT

An electronic device including a substrate, a first conductive layer, a first insulating layer, a second conductive layer, a second insulating layer, a bonding structure, and a chip is provided. The first conductive layer is disposed on the substrate. The first insulating layer is disposed on the first conductive layer and has a first via. The second conductive layer is disposed on the first insulating layer, wherein the second conductive layer is electrically connected to the first conductive layer through the first via. The second insulating layer is disposed on the second conductive layer and has a second via. The bonding structure is disposed on the second insulating layer, wherein the bonding structure is electrically connected to the second conductive layer through the second via. The chip is disposed on the bonding structure.

### CROSS-REFERENCE TO RELATED APPLICATION

This application claims the priority benefit of U.S. provisional application Ser. No. 63/330,319, filed on Apr. 13, 2022 and China application serial no. 202310002856.1, filed on Jan. 3, 2023. The entirety of each of the above-mentioned patent applications is hereby incorporated by reference herein and made a part of this specification.

### BACKGROUND

### Technical Field

The disclosure relates to an electronic device, and in particular relates to a communication device.

### Description of Related Art

In an electronic device, a conductive layer that is disposed as a pad portion is applied, however, there are multiple insulating layers between this conductive layer and external electronic elements (e.g., chips). Therefore, when performing an etching process on these insulating layers to form a via for electrically connecting the conductive layer to external electronic elements, the relatively large thickness and different material properties tend to increase the possibility of defects in the via, which reduces the reliability of the electronic device.

### SUMMARY

The disclosure provides an electronic device, which may reduce the possibility of defects in the formed via, so that the reliability of the electronic device of the disclosure is improved.

According to some embodiments of the disclosure, an electronic device includes a substrate, a first conductive layer, a first insulating layer, a second conductive layer, a second insulating layer, a bonding structure, and a chip. The first conductive layer is disposed on the substrate. The first insulating layer is disposed on the first conductive layer and has a first via. The second conductive layer is disposed on the first insulating layer, in which the second conductive layer is electrically connected to the first conductive layer through the first via. The second insulating layer is disposed on the second conductive layer and has a second via. The bonding structure is disposed on the second insulating layer, in which the bonding structure is electrically connected to the second conductive layer through the second via. The chip is disposed on the bonding structure.

In order to make the aforementioned features and advantages of the disclosure comprehensible, embodiments accompanied with drawings are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure, and together with the description serve to explain principles of the disclosure.

FIG. 1 is a partial cross-sectional schematic view of an electronic device according to a first embodiment of the disclosure.

FIG. 2 is a partial cross-sectional schematic view of an electronic device according to a second embodiment of the disclosure.

FIG. 3 is a partial cross-sectional schematic view of an electronic device according to a third embodiment of the disclosure.

FIG. 4 is a partial cross-sectional schematic view of an electronic device according to a fourth embodiment of the disclosure.

FIG. 5 is a partial cross-sectional schematic view of an electronic device according to a fifth embodiment of the disclosure.

FIG. 6 is a partial cross-sectional schematic view of an electronic device according to a sixth embodiment of the disclosure.

FIG. 7 is a partial cross-sectional schematic view of an electronic device according to a seventh embodiment of the disclosure.

### DETAILED DESCRIPTION OF DISCLOSED EMBODIMENTS

The disclosure may be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

Certain terms may be used throughout the disclosure and the appended patent claims to refer to specific elements. It should be understood by those skilled in the art that electronic device manufacturers may refer to the same elements by different names. The disclosure does not intend to distinguish between elements that have the same function but have different names. In the following description and patent claims, words such as “comprising”, “including”, and “having” are open-ended words, so they should be interpreted as meaning “including but not limited to . . . ”. Accordingly, when the terms “comprising”, “including”, and/or “having” are used in the description of this disclosure, they designate the presence of the corresponding feature, region, step, operation and/or component, but do not exclude the presence of one or more of a corresponding feature, region, step, operation, and/or component.

In the disclosure, wordings used to indicate directions, such as “up,” “down,” “front,” “back,” “left,” and “right,” merely refer to directions in the accompanying drawings. Therefore, the directional wordings are used to illustrate rather than limit the disclosure. In the accompanying drawings, the drawings illustrate the general features of the methods, structures, and/or materials used in the particular embodiments. However, the drawings shall not be interpreted as defining or limiting the scope or nature covered by the embodiments. For example, the relative sizes, thicknesses, and locations of the layers, regions, and/or structures may be reduced or enlarged for clarity.

When a corresponding component (e.g., a film layer or region) is referred to as being “on” another component, it may be directly on the other component or other components may be present therebetween. On the other hand, when a component is referred to as being “directly on” another member, there are no components in between. Additionally, when a component is referred to as being “on” another component, the two are in a top-down relationship when viewed from above, and the component may be above or below the other component, depending on the orientation of the device.

The terms “about”, “substantially” or “generally” are interpreted as within 10% of a given value or range, or interpreted as within 5%, 3%, 2%, 1%, or 0.5% of the given value or range.

The terms such as “first”, “second”, etc. used in the description and the patent claims are used to modify elements, which do not imply and represent that the (or these) elements have any previous ordinal numbers, and also does not represent the order of a certain element and another element, or the order of the manufacturing method. The use of these ordinal numbers is to only clearly distinguish an element with a certain name from another element with the same name. The same terms may not be used in the patent claims and the description, and accordingly, the first component in the description may be the second component in the patent claims.

It should be noted that, in the following embodiments, the features in several different embodiments may be replaced, reorganized, and mixed to complete other embodiments without departing from the spirit of the disclosure. As long as the features of the various embodiments do not violate the spirit of the disclosure or conflict with one another, they may be mixed and matched arbitrarily.

The electrical connection or coupling described in the disclosure may refer to direct connection or indirect connection. In the case of a direct connection, the end points of two elements on a circuit directly connect to each other, or connect to each other through a conductive wire. In the case of indirect connection, a switch, a diode, a capacitor, an inductor, other suitable elements, or a combination thereof, but not limited therein, is between the end points of two elements on a circuit.

In the disclosure, the thickness, length, and width may be measured by adopting a measurement method such as an optical microscope (OM), and the thickness may be measured from a cross-sectional image in an electronic microscope, but not limited thereto. In addition, any two values or directions used for comparison may have certain errors. If a first value is equal to a second value, it implies that there may be an error of about 10% between the first value and the second value; if a first direction is perpendicular to a second direction, an angle between the first direction and the second direction may be between 80 degrees and 100 degrees; if the first direction is parallel to the second direction, an angle between the first direction and the second direction may be between 0 degrees and 10 degrees.

The electronic device of this disclosure may include an antenna device, a display device, a sensing device, a light emitting device, or a splicing device, but is not limited thereto. The electronic device may include a bendable or flexible electronic device. The electronic device includes, for example, a liquid crystal layer or a light emitting diode (LED). The electronic device may include electronic elements. The electronic elements may include passive elements and active elements, such as capacitors, resistors, inductors, variable capacitors, filters, diodes, transistors, sensors, MEMS, liquid crystal chips, etc., but not limited thereto. The diode may include a light emitting diode or a photodiode. The light emitting diode may include, for example, an organic light-emitting diode (OLED), a mini light emitting diode (mini LED), a micro light emitting diode (micro LED), a quantum dot light emitting diode (quantum dot LED), fluorescence, phosphor, or other suitable materials, or a combination thereof, but not limited thereto. The sensor may, for example, include capacitive sensors, optical sensors, electromagnetic sensors, fingerprint sensors (FPS), touch sensors, antennas, or pen sensors, etc., but not limited thereto.

Exemplary embodiments of this disclosure are exemplified below, in which an electronic device is used as an antenna device for illustration, and the same reference numerals in the drawings and the descriptions indicate the same or similar parts.

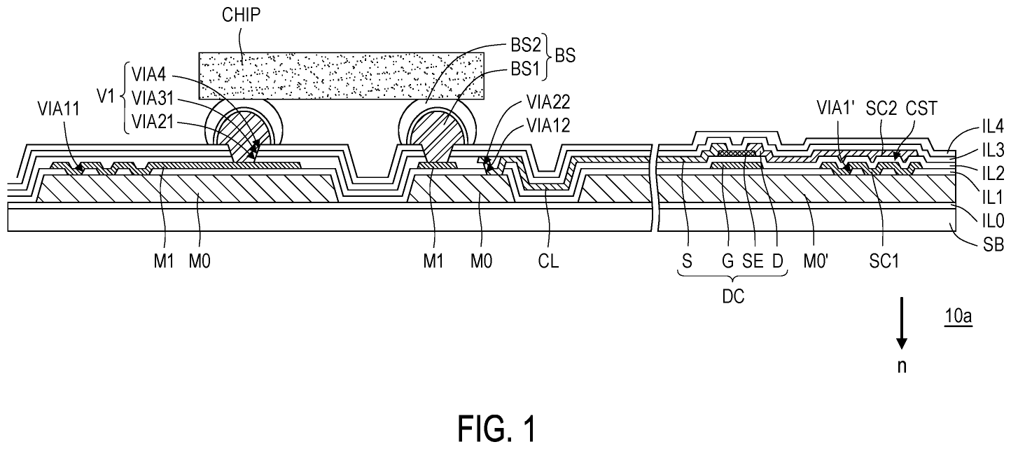

FIG. 1 is a partial cross-sectional schematic view of an electronic device according to a first embodiment of the disclosure.

Referring to FIG. 1, the electronic device 10a of this embodiment includes a substrate SB, a conductive layer M0, an insulating layer ILL a conductive layer M1, an insulating layer IL2, a bonding structure BS, and a chip CHIP. It is worth noting that the electronic device 10a of this embodiment may include, for example, an antenna device, a display device, a sensing device, a light emitting device or a splicing device, but the disclosure is not limited thereto. In this embodiment, the electronic device 10a is an antenna device. For example, the electronic device 10a may be suitable for the communication field, the radar/lidar field, and the reconfigurable intelligent surface (RIS) technology, or other suitable fields/technologies, but the disclosure is not limited thereto. In some embodiments, the electronic device 10a may be a bendable or flexible electronic device, but the disclosure is not limited thereto.

The material of the substrate SB may be, for example, glass, plastic, or a combination thereof. For example, the material of the substrate SB may include quartz, sapphire, silicon (Si), germanium (Ge), silicon carbide (SiC), gallium nitride (GaN), silicon germanium (SiGe), polymethyl methacrylate (PMMA), polycarbonate (PC), polyimide (PI), polyethylene terephthalate (PET), or other suitable materials, or a combination thereof, and the disclosure is not limited thereto.

The conductive layer M0 is, for example, disposed on the substrate SB. In some embodiments, the conductive layer M0 may serve as a pad portion of the electronic device 10a. In detail, in this embodiment, the conductive layer M0 is a pad portion used for electrically connecting the chip CHIP to the driving element described subsequently, but the disclosure is not limited thereto. In some embodiments, the material of the conductive layer M0 may include low-resistance materials such as copper, titanium, silver, gold, aluminum, tin, nickel, or combinations thereof. However, the material of the conductive layer M0 may also be, for example, other suitable materials or a combination thereof, and this disclosure is not limited thereto. In addition, the conductive layer M0 may, for example, include a single-layer structure or a multi-layer structure. For example, in some embodiments, the conductive layer M0 may include a single copper layer, but the disclosure is not limited thereto. In some other embodiments, the conductive layer M0 may include a stacked structure stacked on each other. For example, the conductive layer M0 may be a multi-layer structure, for example, a titanium nitride layer, a copper layer, and a titanium nitride layer stacked in this order, but the disclosure is not limited thereto.

The insulating layer IL1 is, for example, disposed on the substrate SB. In this embodiment, the insulating layer IL1 is disposed on the conductive layer M0 and partially covers the conductive layer M0, that is, the insulating layer IL1 has a via VIA11 and a via VIA12 exposing a portion of the conductive layer M0, but the disclosure is not limited thereto. The material of the insulating layer IL1 may be, for example, an inorganic material (e.g., silicon oxide, silicon nitride, silicon oxynitride, or a stacked layer of at least two of the materials thereof), an organic material (e.g., polyimide resin, epoxy resin, or acrylic resin) or a combination thereof, but the disclosure is not limited thereto.

The conductive layer M1 is, for example, disposed on the substrate SB. In this embodiment, the conductive layer M1 is disposed on the insulating layer IL1 and is electrically connected to the conductive layer M0 through the via VIA11. In some embodiments, the conductive layer M1 may include a single-layer structure, but the disclosure is not limited thereto. In some embodiments, the conductive layer M1 may be a multi-layer structure, but the disclosure is not limited thereto. In addition, the material included in the conductive layer M1 and the material included in the conductive layer M0 may be the same or similar, and are not repeated herein.

The insulating layer IL2 is, for example, disposed on the substrate SB. In this embodiment, the insulating layer IL2 is disposed on the conductive layer M1 and partially covers the conductive layer M1, that is, the insulating layer IL2 has a via VIA21 exposing a portion of the conductive layer M1, but the disclosure is not limited thereto. In addition, the insulating layer IL2 also has a via VIA22, in which the via VIA22 is connected to the via VIA12 of the insulating layer IL1 to expose a portion of the conductive layer M0. The material of the insulating layer IL2 may be, for example, an inorganic material (e.g., silicon oxide, silicon nitride, silicon oxynitride, or a stacked layer of at least two of the materials thereof), an organic material (e.g., polyimide resin, epoxy resin, or acrylic resin) or a combination thereof, but the disclosure is not limited thereto.

The bonding structure BS is, for example, disposed on the insulating layer IL2. In this embodiment, the bonding structure BS may be electrically connected to the conductive layer M1 through the via VIA21. In this embodiment, the bonding structure BS includes the solder BS1 and the bump BS2. The solder BS1 is disposed on the bump BS2, and a portion of the bump BS2 is disposed in the via VIA21 to be electrically connected to the conductive layer M1, but the disclosure is not limited thereto. In other embodiments, the bonding structure BS may include structures such as solder balls and conductive pillars. The material of the bump BS2 may include, for example, metal or metal alloy. For example, the material of the bump BS2 may be an alloy of gold and nickel, which may be formed by electroless nickel immersion gold (ENIG) technology, but the disclosure is not limited thereto.

The chip CHIP is, for example, disposed on the bonding structure BS. In some embodiments, the chip CHIP may include communication elements. In detail, the chip CHIP may include, for example, a varactor diode, a variable capacitor, a radio frequency radiation element, a variable resistor, a phase shifter, an amplifier, an antenna, a biometric sensor, a graphene sensors, other suitable elements, or combinations thereof. For example, the chip CHIP of this embodiment is a capacitive modulating element, which includes a varactor diode. The varactor diode may provide different capacitance values according to the signals provided by the driving elements which are described subsequently, that is, the capacitance value of the varactor diode may be changed by changing the voltage across the varactor diode. Therefore, by adjusting the capacitance value of the varactor diode, the electronic device 10a of this embodiment may adjust the operating frequency band, but the disclosure is not limited thereto.

In this embodiment, the electronic device 10a may further include an insulating layer ILO.

The insulating layer IL0 is, for example, disposed on the substrate SB. In this embodiment, the insulating layer IL0 is disposed between the substrate SB and the conductive layer M0. The material of the insulating layer ILO may be selected to include a material with an appropriate thermal expansion coefficient or a material that is opposite to the stress generated when the conductive layer M0 undergoes a heating process, so as to reduce the warping phenomenon generated in the substrate SB; alternatively, the material of the insulating layer ILO may be selected to have good adhesion with the conductive layer M0, and the disclosure is not limited thereto. The material of the insulating layer ILO may be, for example, an inorganic material (e.g., silicon oxide, silicon nitride, silicon oxynitride, or a stacked layer of at least two of the materials thereof), but the disclosure is not limited thereto.

In this embodiment, the electronic device 10a may further include a conductive layer M0′.

The conductive layer M0′ is, for example, disposed on the substrate SB, and belongs to the same layer as the conductive layer M0. The conductive layer M0′ may be, for example, separated from or connected to the conductive layer M0, and the disclosure is not limited thereto. In some embodiments, the conductive layer M0′ may surround the conductive layer M0 that serve as the pad portion, but the disclosure is not limited thereto. The conductive layer M0′ may be used, for example, as a ground plate, an electrostatic discharge (ESD) protection layer, an electromagnetic interference (EMI) shielding layer, a heat dissipation layer, or other layers with other purposes of the electronic device 10a, but the disclosure is not limited thereto. In some embodiments, the conductive layer M0′ may occupy more than 85% of the surface area of the substrate SB in the top view direction n of the substrate SB, so as to shield unwanted electromagnetic waves, but the disclosure is not limited thereto. The material and structure included in the conductive layer M0′ and the material and structure included in the conductive layer M0 may be the same or similar, and are not repeated herein. In addition, in this embodiment, the insulating layer IL1 is also disposed on the conductive layer M0′ and partially covers the conductive layer M0′. That is, the insulating layer IL1 has a via VIA1′ exposing a portion of the conductive layer M′, but the disclosure is not limited thereto.

In this embodiment, the electronic device 10a may further include a driving element DC.

The driving element DC is, for example, disposed on the substrate SB and electrically connected to the chip CHIP. The driving element DC may be disposed on the substrate SB in an array arrangement, a staggered arrangement (e.g., in a pentile manner) or other manners, but the disclosure is not limited thereto. In some embodiments, the driving element DC may include an active element, a passive element, or a combination thereof. In this embodiment, the driving element DC is a thin film transistor, but the disclosure is not limited thereto. In detail, the driving element DC may include, for example, a gate G, a source S, a drain D, and a semiconductor layer SE. The gate G, for example, belongs to the same layer as the conductive layer M1, the semiconductor layer SE is, for example, disposed between a conductive layer (gate G) and another conductive layer (source S and drain D), and electrically connected to another conductive layer (source S and drain D). One of the gate G, the source S, and the drain D may be at least one conductive pattern in the conductive layer M1, the conductive layer M2, or the conductive layer M3 described subsequently, but the disclosure is not limited thereto. The material of the semiconductor layer SE may include, for example, low temperature polysilicon (LTPS), metal oxide, amorphous silicon (a-Si), or a combination thereof, but the disclosure is not limited thereto.

For example, the material of the semiconductor layer SE may include but not limited to amorphous silicon, polysilicon, germanium, compound semiconductors (e.g., gallium nitride, silicon carbide, gallium arsenide, gallium phosphide, indium phosphide, indium arsenide, and/or or indium antimonide), alloy semiconductors (e.g., SiGe alloys, GaAsP alloys, AlInAs alloys, AlGaAs alloys, GaInAs alloys, GaInP alloys, GaInAsP alloys), or a combination thereof. The material of the semiconductor layer SE may also include but not limited to metal oxides, such as indium gallium zinc oxide (IGZO), indium zinc oxide (IZO), indium gallium zinc tin oxide (IGZTO), or organic semiconductors including polycyclic aromatic compounds, or a combination thereof. In this embodiment, the material of the semiconductor layer SE is amorphous silicon, but the disclosure is not limited thereto. The gate G, for example, at least partially overlaps the semiconductor layer SE in the top view direction n of the substrate SB. The source S and the drain D are, for example, separated from each other, and cover at least a portion of the semiconductor layer SE and are electrically connected to the semiconductor layer SE. It should be noted that although this embodiment shows that the driving element DC may be any bottom-gate thin film transistor known to those skilled in the art, the disclosure is not limited thereto. In some embodiments, the conductive layer M0′ may at least partially overlap the driving element DC in the top view direction n of the substrate SB. In this embodiment, the conductive layer M0′ overlaps the driving element DC in the top view direction n of the substrate SB, but the disclosure is not limited thereto.

In some other embodiments, the driving element DC may be a circuit chip. For example, the driving element DC may include a substrate (not shown), a driving circuit (not shown) disposed on the substrate, or other suitable components, and the disclosure is not limited thereto. The driving element DC may be, for example, disposed on the substrate SB in the manner that a chip is disposed on the substrate. In detail, the substrate of the driving element DC may be a flexible substrate, a glass substrate, or other suitable substrates, and the driving element DC may be disposed on the substrate SB in a manner of chip on panel (COP), for example, but this disclosure is not limited thereto.

In this embodiment, the electronic device 10a may further include a wiring CL.

The wiring CL is, for example, disposed on the insulating layer IL2, and for example, belongs to the same layer as the source S and the drain D. In this embodiment, one end of the wiring CL is electrically connected to the source S, and the other end of the wiring CL is electrically connected to the conductive layer M0 through the via VIA12 and the via VIA22 that are connected to each other. Based on this, the driving element DC may be, for example, electrically connected to the conductive layer M0 serving as a pad portion through the wiring CL, thereby being electrically connected to the chip CHIP.

In this embodiment, the electronic device 10a may further include a scan line SL and a data line DL.

The scan line SL and the data line DL are, for example, disposed on the substrate SB. In this embodiment, the scan line SL and the data line DL are disposed on the conductive layer M0 (with an insulating layer IL1 at least therebetween). The scan line SL, for example, belongs to the same layer as the gate G, and the data line DL, for example, belongs to the same layer as the source S, the drain D, and the wiring CL. In some embodiments, the scan line SL is electrically connected to the gate G of the driving element DC, and the data line DL is electrically connected to the source S of the driving element DC for operating the driving element DC.

In this embodiment, the electronic device 10a may further include a storage capacitor CST.

The storage capacitor CST is, for example, disposed on the substrate SB and electrically connected to the driving element DC. Specifically, in this embodiment, the storage capacitor CST may be formed by a storage electrode SC1, a storage electrode SC2, and the insulating layer IL2 disposed between the storage electrode SC1 and the storage electrode SC2. The storage electrode SC1 belongs to the same layer as the gate G and the scan line SL, and the storage electrode SC2 belongs to the same layer as the source S, the drain D, the data line DL, and the wiring CL. The storage electrode SC1 may be electrically connected to the conductive layer M0′ through the via VIA1′ penetrating the insulating layer IL1, and the storage electrode SC2 may be, for example, electrically connected to the drain D, but the disclosure is not limited thereto. Based on this, the storage electrode SC1, the storage electrode SC2, and the insulating layer IL2 disposed between the storage electrode SC1 and the storage electrode SC2 may form the storage capacitor CST.

In this embodiment, the electronic device 10a may further include an insulating layer IL3.

The insulating layer IL3 is, for example, disposed on the substrate SB. In this embodiment, the insulating layer IL3 is disposed on the conductive layer M1 and covers the conductive layer M1. In addition, in this embodiment, the insulating layer IL3 has a via VIA31, in which the via VIA31 is connected to the via VIA21 of the insulating layer IL2 to expose a portion of the conductive layer M1, but the disclosure is not limited thereto. The material of the insulating layer IL3 may be, for example, an inorganic material (e.g., silicon oxide, silicon nitride, silicon oxynitride, or a stacked layer of at least two of the materials thereof), an organic material (e.g., polyimide resin, epoxy resin, or acrylic resin) or a combination thereof, but the disclosure is not limited thereto.

In this embodiment, the electronic device 10a may further include an insulating layer IL4.

The insulating layer IL4 is, for example, disposed on the substrate SB. In this embodiment, the insulating layer IL4 is disposed on the insulating layer IL3. In addition, in this embodiment, the insulating layer IL4 has a via VIA4, in which the via VIA4 is connected to the via VIA31 of the insulating layer IL3 and the via VIA21 of the insulating layer IL2 to expose a portion of the conductive layer M1, but the disclosure is not limited thereto. The material of the insulating layer IL4 may be, for example, an inorganic material (e.g., silicon oxide, silicon nitride, silicon oxynitride, or a stacked layer of at least two of the materials thereof), an organic material (e.g., polyimide resin, epoxy resin, or acrylic resin) or a combination thereof, but the disclosure is not limited thereto.

Based on this, in this embodiment, the via VIA21, the via VIA31 and the via VIA4 are connected to each other to form a via V1, and the chip CHIP is electrically connected to the conductive layer M0 that serves as a pad portion through (1) the via V1 and (2) the conductive layer M1 (the conductive layer M1 is connected to the conductive layer M0 through another via VIA11 that is not connected to the via V1) disposed between the insulating layer IL1 and the insulating layer IL2. Through the design of a conductive layer M1 disposed between the conductive layer M0 and the chip CHIP, the conductive layer M1 may be electrically connected to the conductive layer M0 and the chip CHIP through different vias for the purpose of connection switching. Through the design of a conductive layer M1 disposed between the conductive layer M0 and the chip CHIP, the conductive layer M1 may be electrically connected to the conductive layer M0 and the chip CHIP through different vias for the purpose of connection transition. Therefore, the chip CHIP may be prevented from being electrically connected to the conductive layer M0 of the pad portion through a single via, that is, the possibility of a single via penetrating through many insulating layers and causing defects may be avoided. Using multiple vias and conductive layer for connection transitions may relatively reduce the number of insulating layers penetrated by the vias, thereby reducing the possibility of defects in the via V1 and improving the reliability of the electronic device 10a of this embodiment.

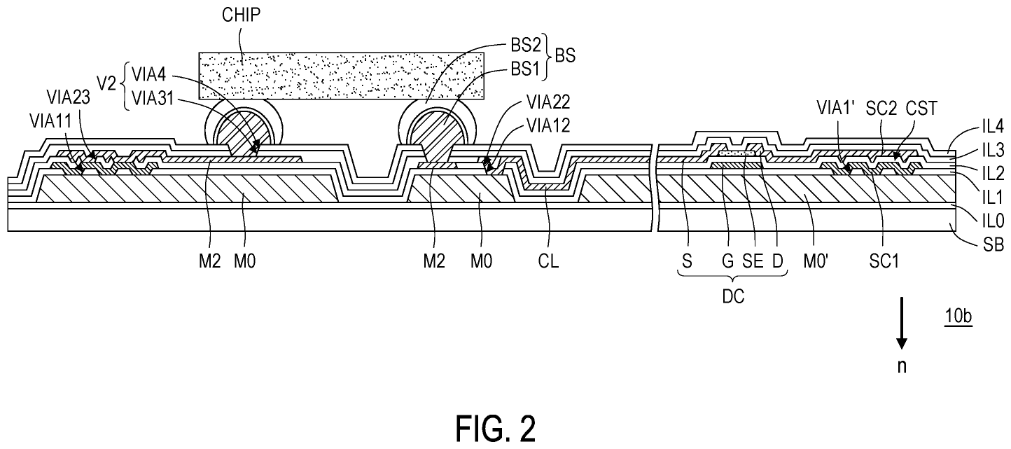

FIG. 2 is a partial cross-sectional schematic view of an electronic device according to a second embodiment of the disclosure. The embodiment of FIG. 2 uses the reference numerals and a portion of the content of the embodiment of FIG. 1, in which the same or similar reference numerals are used to denote the same or similar elements, and the description of the same technical content is omitted.

Referring to FIG. 2, the main difference between the electronic device 10b of this embodiment and the aforementioned electronic device 10a is that the electronic device 10b further includes a conductive layer M2. In this embodiment, the chip CHIP is electrically connected to the conductive layer M2, and the conductive layer M2 is electrically connected to the conductive layer M1. In addition, the conductive layer M2, for example, belongs to the same layer as the source S, the drain D, the data line DL, the wiring CL and the storage electrode SC2.

Specifically, the conductive layer M1 of this embodiment is disposed between the insulating layer IL1 and the conductive layer M2, and the insulating layer IL2 of this embodiment is disposed between the conductive layer M1 and the conductive layer M2, and a via VIA23 is further included without including the via VIA21. The conductive layer M2 is electrically connected to the conductive layer M1 through the via VIA23, and the conductive layer M1 is electrically connected to the conductive layer M0 through the via VIA11.

In addition, in this embodiment, the semiconductor layer SE is disposed between the conductive layer M2 (which belongs to the same layer as the source S and the drain D) and the conductive layer M1 (which belongs to the same layer as the gate G). Alternatively, in this embodiment, the semiconductor layer SE is disposed between the insulating layer IL2 and the conductive layer M2 (which belongs to the same layer as the source S and the drain D).

Based on this, in this embodiment, the via VIA31 and the via VIA4 are connected to each other to form a via V2, and the chip CHIP is electrically connected to the conductive layer M0 that serves as a pad portion through (1) the via V2, (2) the conductive layer M1 (the conductive layer M1 is connected to the conductive layer M0 through another via VIA11 that is not connected to the via V2) disposed between the insulating layer IL1 and the insulating layer IL2, and (3) the conductive layer M2 (the conductive layer M2 is connected to the conductive layer M1 through another via VIA23 that is not connected to the via V2) disposed between the insulating layer IL2 and the insulating layer IL3. Through the design of a conductive layer M1 and a conductive layer M2 disposed between the conductive layer M0 and the chip CHIP, the conductive layer M1 and/or the conductive layer M2 may be electrically connected to the conductive layer M0 and the chip CHIP through different vias for the purpose of connection transition. Therefore, the chip CHIP may be prevented from being electrically connected to the conductive layer M0 of the pad portion through a single via, that is, the possibility of a single via penetrating through many insulating layers and causing defects may be avoided. Using multiple vias and conductive layer for connection transitions may relatively reduce the number of insulating layers penetrated by the vias, thereby reducing the possibility of defects in the via and improving the reliability of the electronic device 10b of this embodiment.

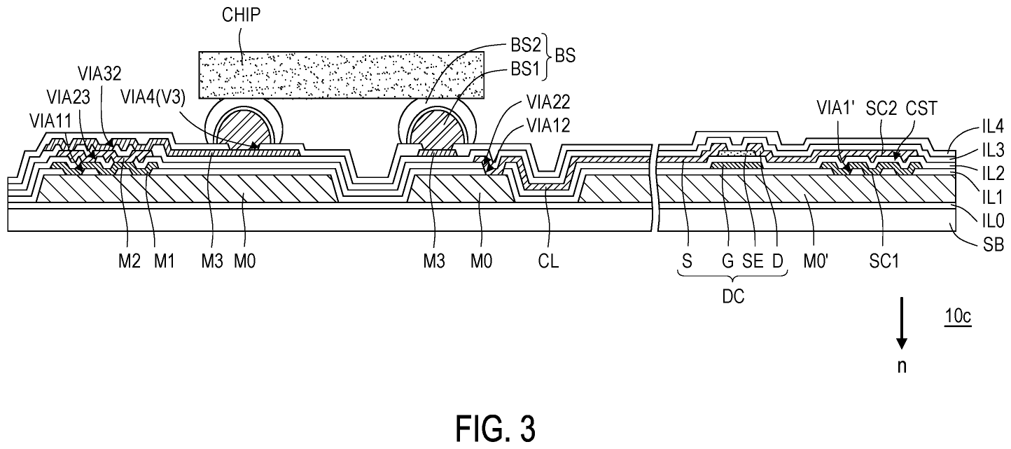

FIG. 3 is a partial cross-sectional schematic view of an electronic device according to a third embodiment of the disclosure. It is noted that the embodiment of FIG. 3 may use the reference numerals and a part of the contents of the embodiment of FIG. 2, and the same or similar reference numerals are used to denote the same or similar elements, and the description of the same technical content is omitted.

Referring to FIG. 3, the main difference between the electronic device 10c of this embodiment and the aforementioned electronic device 10b is that the electronic device 10c further includes a conductive layer M3. In this embodiment, the chip CHIP is electrically connected to the conductive layer M3, the conductive layer M3 is electrically connected to the conductive layer M2, the conductive layer M2 is electrically connected to the conductive layer M1, and the conductive layer M1 is electrically connected to the conductive layer M0. In addition, the driving element DC is located between the conductive layer M0 and the conductive layer M3. In some embodiments, the driving element DC may partially overlap the conductive layer M0 and the conductive layer M3 in the top view direction n of the substrate SB, but the disclosure is not limited thereto. In other embodiments, the driving element DC may partially overlap the conductive layer M0 and the conductive layer M3 in a specific direction (there is a non-0 degree or non-90 degree included angle with the top view direction n of the substrate SB), so that the driving element DC and the conductive layer M0 and/or the conductive layer M3 are misaligned in the top view direction n of the substrate SB. It is worth noting that the components located between the conductive layer M0 and the conductive layer M3 may include, for example, other film layers in addition to the driving element DC, and the disclosure is not limited thereto.

In detail, the conductive layer M2 of this embodiment is disposed between the insulating layer IL2 (or the insulating layer IL1) and the conductive layer M3, and the insulating layer IL3 of this embodiment is disposed between the conductive layer M2 and the conductive layer M3, and a via VIA32 is further included without including the via VIA31. The conductive layer M3 is electrically connected to the conductive layer M2 through the via VIA32.

Based on this, in this embodiment, the chip CHIP is electrically connected to the conductive layer M0 that serves as a pad portion through (1) the via V3, (2) the conductive layer M1 (the conductive layer M1 is connected to the conductive layer M0 through another via VIA11 that is not connected to the via V3) disposed between the insulating layer IL1 and the insulating layer IL2, (3) the conductive layer M2 (the conductive layer M2 is connected to the conductive layer M1 through another via VIA23 that is not connected to the via V3) disposed between the insulating layer IL2 and the insulating layer IL3, and (4) the conductive layer M3 (the conductive layer M3 is connected to the conductive layer M2 through another via VIA32 that is not connected to the via V3) disposed between the insulating layer IL3 and the insulating layer IL4. Through the design of a conductive layer M1, a conductive layer M2, and a conductive layer M3 disposed between the conductive layer M0 and the chip CHIP, the conductive layer M1, the conductive layer M2, and/or the conductive layer M3 may be electrically connected to the conductive layer M0 and the chip CHIP through different vias for the purpose of connection transition. Therefore, the chip CHIP may be prevented from being electrically connected to the conductive layer M0 of the pad portion through a single via, that is, the possibility of a single via penetrating through many insulating layers and causing defects may be avoided. Using multiple vias and conductive layer for connection transitions may relatively reduce the number of insulating layers penetrated by the vias, thereby reducing the possibility of defects in the via and improving the reliability of the electronic device 10c of this embodiment.

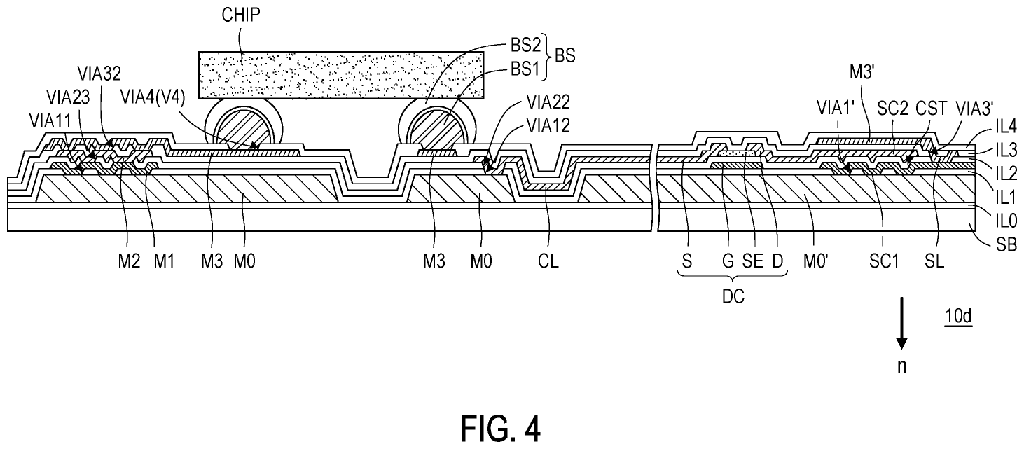

FIG. 4 is a partial cross-sectional schematic view of an electronic device according to a fourth embodiment of the disclosure. It is noted that the embodiment of FIG. 4 may use the reference numerals and a part of the contents of the embodiment of FIG. 3, and the same or similar reference numerals are used to denote the same or similar elements, and the description of the same technical content is omitted.

Referring to FIG. 4, the main difference between the electronic device 10d of this embodiment and the aforementioned electronic device 10c is that the electronic device 10d further includes a conductive layer M3′. The conductive layer M3′ and the conductive layer M3 belong to the same layer, and the conductive layer M3′ is disposed between the insulating layer IL4 and the scan line SL in the top view direction n of the substrate SB. In some embodiments, the conductive layer M3′ may partially overlap the insulating layer IL4 and the scan line SL in the top view direction n of the substrate SB, but the disclosure is not limited thereto. In some other embodiments, the conductive layer M3′ may partially overlap the insulating layer IL4 and the scan line SL in a specific direction (there is a non-0 degree or non-90 degree included angle with the top view direction n of the substrate SB), so that the conductive layer M3′ and the insulating layer IL4 and/or the scan line SL are misaligned in the top view direction n of the substrate SB. It is worth noting that the components located between the insulating layer IL4 and the scan line SL may include, for example, other film layers in addition to the conductive layer M3′, and the disclosure is not limited thereto.

In this embodiment, the scan line SL may be electrically connected to the conductive layer M3′ through the via VIA3′ penetrating the insulating layer IL2 and the insulating layer IL3. Since the conductive layer M3′ is disposed farther away from the conductive layer M0′ than the scan line SL, the distance between the scan line SL and the conductive layer M0′ may be increased by electrically connecting the scan line SL to the conductive layer M3′, thereby the capacitive load generated by the scan line SL may be reduced (the capacitive load is inversely proportional to the distance between the two conductive layers), and the signal transmission quality of the electronic device 10d may be improved. Furthermore, by electrically connecting the scan line SL to the conductive layer M3′, the cross-sectional area of the scan line SL may be increased, thereby reducing the impedance generated by the scan line SL (the impedance value is inversely proportional to the cross-sectional area of the conductive layer). Thus, the signal transmission quality of the electronic device 10d may be improved.

In general, through the design of electrically connecting the scan line SL to the conductive layer M3′, the resistance-capacitance loading (RC loading) of the electronic device 10d may be reduced, and the signal transmission quality of the electronic device 10d may be improved.

It is worth noting that, although not shown in the drawings, other embodiments of the disclosure may also electrically connect the data line DL to the conductive layer M3′, which may also reduce the resistance-capacitance loading of the electronic device 10d.

Based on this, in this embodiment, the chip CHIP is electrically connected to the conductive layer M0 that serves as a pad portion through (1) the via V4, (2) the conductive layer M1 (the conductive layer M1 is connected to the conductive layer M0 through another via VIA11 that is not connected to the via V4) disposed between the insulating layer IL1 and the insulating layer IL2, (3) the conductive layer M2 (the conductive layer M2 is connected to the conductive layer M1 through another via VIA23 that is not connected to the via V4) disposed between the insulating layer IL2 and the insulating layer IL3, and (4) the conductive layer M3 (the conductive layer M3 is connected to the conductive layer M2 through another via VIA32 that is not connected to the via V4) disposed between the insulating layer IL3 and the insulating layer IL4. Through the design of a conductive layer M1, a conductive layer M2, and a conductive layer M3 disposed between the conductive layer M0 and the chip CHIP, the conductive layer M1, the conductive layer M2, and/or the conductive layer M3 may be electrically connected to the conductive layer M0 and the chip CHIP through different vias for the purpose of connection transition. Therefore, the chip CHIP may be prevented from being electrically connected to the conductive layer M0 of the pad portion through a single via, that is, the possibility of a single via penetrating through many insulating layers and causing defects may be avoided. Using multiple vias and conductive layer for connection transitions may relatively reduce the number of insulating layers penetrated by the vias, thereby reducing the possibility of defects in the via and improving the reliability of the electronic device 10d of this embodiment.

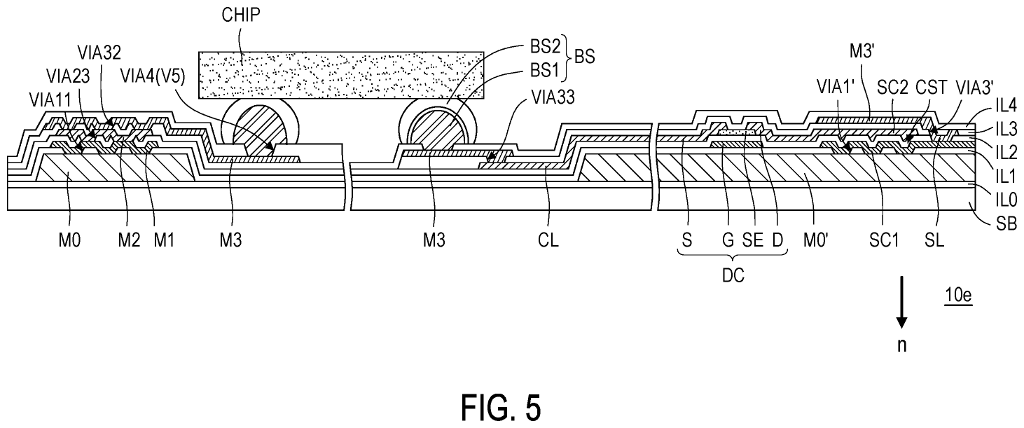

FIG. 5 is a partial cross-sectional schematic view of an electronic device according to a fifth embodiment of the disclosure. It is noted that the embodiment of FIG. 5 may use the reference numerals and a part of the contents of the embodiment of FIG. 4, and the same or similar reference numerals are used to denote the same or similar elements, and the description of the same technical content is omitted.

Referring to FIG. 5, the main difference between the electronic device 10e of this embodiment and the aforementioned electronic device 10d is that the conductive layer M0 of the electronic device 10e does not overlap with the chip CHIP and/or the bonding structure BS in the top view direction n of the substrate SB, in which the chip CHIP may be electrically connected to the driving element DC through the conductive layer M3 and the via VIA33. Under this design, the impact of topographical differences caused by the disposition of the conductive layer M0 may be reduced.

Based on this, in this embodiment, the chip CHIP is electrically connected to the conductive layer M0 that serves as a pad portion through (1) the via V5, (2) the conductive layer M1 (the conductive layer M1 is connected to the conductive layer M0 through another via VIA11 that is not connected to the via V5) disposed between the insulating layer IL1 and the insulating layer IL2, (3) the conductive layer M2 (the conductive layer M2 is connected to the conductive layer M1 through another via VIA23 that is not connected to the via V5) disposed between the insulating layer IL2 and the insulating layer IL3, and (4) the conductive layer M3 (the conductive layer M3 is connected to the conductive layer M2 through another via VIA32 that is not connected to the via V5) disposed between the insulating layer IL3 and the insulating layer IL4. Through the design of a conductive layer M1, a conductive layer M2, and a conductive layer M3 disposed between the conductive layer M0 and the chip CHIP, the conductive layer M1, the conductive layer M2, and/or the conductive layer M3 may be electrically connected to the conductive layer M0 and the chip CHIP through different vias for the purpose of connection transition. Therefore, the chip CHIP may be prevented from being electrically connected to the conductive layer M0 of the pad portion through a single via, that is, the possibility of a single via penetrating through many insulating layers and causing defects may be avoided. Using multiple vias and conductive layer for connection transitions may relatively reduce the number of insulating layers penetrated by the vias, thereby reducing the possibility of defects in the via and improving the reliability of the electronic device 10e of this embodiment.

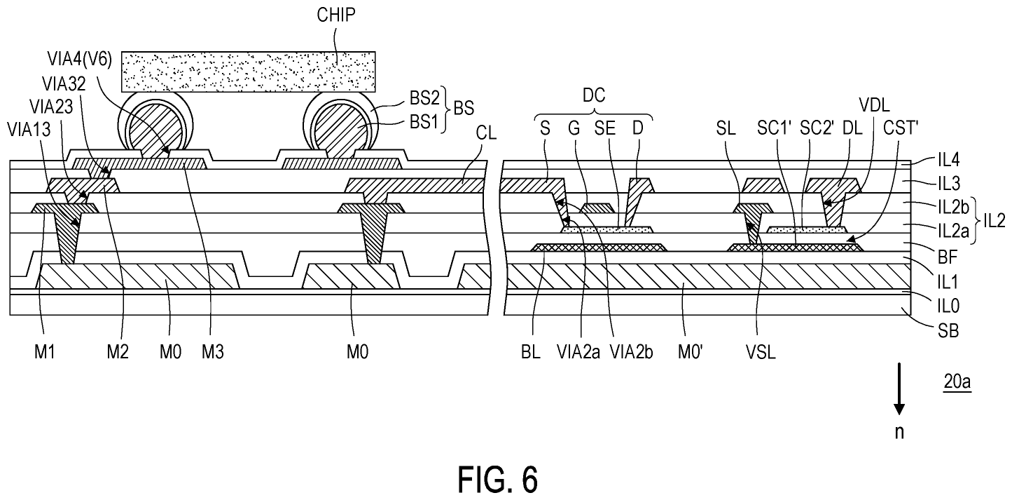

FIG. 6 is a partial cross-sectional schematic view of an electronic device according to a sixth embodiment of the disclosure. It is noted that the embodiment of FIG. 6 may use the reference numerals and a part of the contents of the embodiment of FIG. 3, and the same or similar reference numerals are used to denote the same or similar elements, and the description of the same technical content is omitted.

Referring to FIG. 6, the main difference between the electronic device 20a of this embodiment and the aforementioned electronic device 10c is that the driving element DC′ included in the electronic device 20a is a top-gate thin film transistor, in which the material of the semiconductor layer SE in the driving element DC′ includes low-temperature polysilicon, and the semiconductor layer SE is disposed between the insulating layer IL1 and the conductive layer M2 (which belongs to the same layer as the source S and the drain D). In addition, the driving element DC′ is located between the conductive layer M0 and the conductive layer M3. In some embodiments, the driving element DC′ may partially overlap the conductive layer M0 and the conductive layer M3 in the top view direction n of the substrate SB, but the disclosure is not limited thereto. In other embodiments, the driving element DC′ may partially overlap the conductive layer M0 and the conductive layer M3 in a specific direction (there is a non-0 degree or non-90 degree included angle with the top view direction n of the substrate SB), so that the driving element DC′ and the conductive layer M0 and/or the conductive layer M3 are misaligned in the top view direction n of the substrate SB. It is worth noting that the components located between the conductive layer M0 and the conductive layer M3 may, for example, include other film layers besides the driving element DC′, and the disclosure is not limited thereto.

In some other embodiments, the driving element DC′ may be a circuit chip. For example, the driving element DC′ may include a substrate (not shown), a driving circuit (not shown) disposed on the substrate, or other suitable components, and the disclosure is not limited thereto. The driving element DC′ may be, for example, disposed on the substrate SB in the manner that a chip is disposed on the substrate. In detail, the substrate of the driving element DC′ may be a flexible substrate, a glass substrate, or other suitable substrates, and the driving element DC′ may be disposed on the substrate SB in a manner of chip on panel (COP), for example, but this disclosure is not limited thereto.

In detail, the insulating layer IL2 of this embodiment includes an insulating layer IL2a and an insulating layer IL2b disposed on the semiconductor layer SE, in which the insulating layer IL2b is disposed on the insulating layer IL2a. Each of the insulating layer IL2a and the insulating layer IL2b includes, for example, a via VIA2a and a via VIA2b, and the via VIA2a is connected to the via VIA2b to expose a portion of the semiconductor layer SE, and the source S and the drain D disposed on the insulating layer IL2b may be electrically connected to the semiconductor layer SE through the connected via VIA2a and via VIA2b.

In this embodiment, the electronic device 20a may further include a light shielding layer B L.

The light shielding layer BL is, for example, disposed on the substrate SB. In this embodiment, the light shielding layer BL is disposed on the insulating layer IL1 and located between the substrate SB and the channel region of the semiconductor layer SE, and the light shielding layer BL at least partially overlaps with the channel region of the semiconductor layer SE in the top view direction n of the substrate SB, thereby reducing the degradation of the channel region due to external ambient light. In some embodiments, the material of the light shielding layer BL may include materials with a transmittance lower than 30%, but the disclosure is not limited thereto.

In this embodiment, the electronic device 20a may further include a buffer layer BF.

The buffer layer BF is, for example, disposed on the substrate SB. In this embodiment, the buffer layer BF is disposed on the insulating layer IL1 and covers the light shielding layer BL, but the disclosure is not limited thereto. The material of the buffer layer BF may be, for example, an inorganic material (e.g., silicon oxide, silicon nitride, silicon oxynitride, or a stacked layer of at least two of the materials thereof), but the disclosure is not limited thereto.

In addition, the storage capacitor CST′ of this embodiment is, for example, disposed on the substrate SB. In detail, in this embodiment, the electronic device 20a may include a storage electrode SC1′ and a storage electrode SC2′. The storage electrode SC1′ and the light shielding layer BL belong to the same layer, and the storage electrode SC2′ and the semiconductor layer SE belong to the same layer. The storage electrode SC1′ can, for example, be electrically connected to the scan line SL through the via VSL penetrating the buffer layer BF and the insulating layer IL2a, and the storage electrode SC2′ can, for example, be electrically connected to the data line DL through the via VDL penetrating the insulating layer IL2a and the insulating layer IL2b, but the disclosure is not limited thereto. Based on this, the storage electrode SC1′, the storage electrode SC2′, and the buffer layer BF disposed between the storage electrode SC1′ and the storage electrode SC2′ may form a storage capacitor CST′.

In addition, in this embodiment, the conductive layer M1 is electrically connected to the conductive layer M0 through the via VIA13 penetrating the insulating layer IL2a, the buffer layer BF, and the insulating layer ILL

Based on this, in this embodiment, the chip CHIP is electrically connected to the conductive layer M0 that serves as a pad portion through (1) the via V6, (2) the conductive layer M1 (the conductive layer M1 is connected to the conductive layer M0 through another via VIA13 that is not connected to the via V6) disposed between the insulating layer IL1 and the insulating layer IL2b, (3) the conductive layer M2 (the conductive layer M2 is connected to the conductive layer M1 through another via VIA23 that is not connected to the via V6) disposed between the insulating layer IL2 and the insulating layer IL3, and (4) the conductive layer M3 (the conductive layer M3 is connected to the conductive layer M2 through another via VIA32 that is not connected to the via V6) disposed between the insulating layer IL3 and the insulating layer IL4. Through the design of a conductive layer M1, a conductive layer M2, and a conductive layer M3 disposed between the conductive layer M0 and the chip CHIP, the conductive layer M1, the conductive layer M2, and/or the conductive layer M3 may be electrically connected to the conductive layer M0 and the chip CHIP through different vias for the purpose of connection transition. Therefore, the number of insulating layers penetrated by the via V6 may be relatively reduced, thereby reducing the possibility of defects in the via V6, so that the reliability of the electronic device 20a of this embodiment is improved.

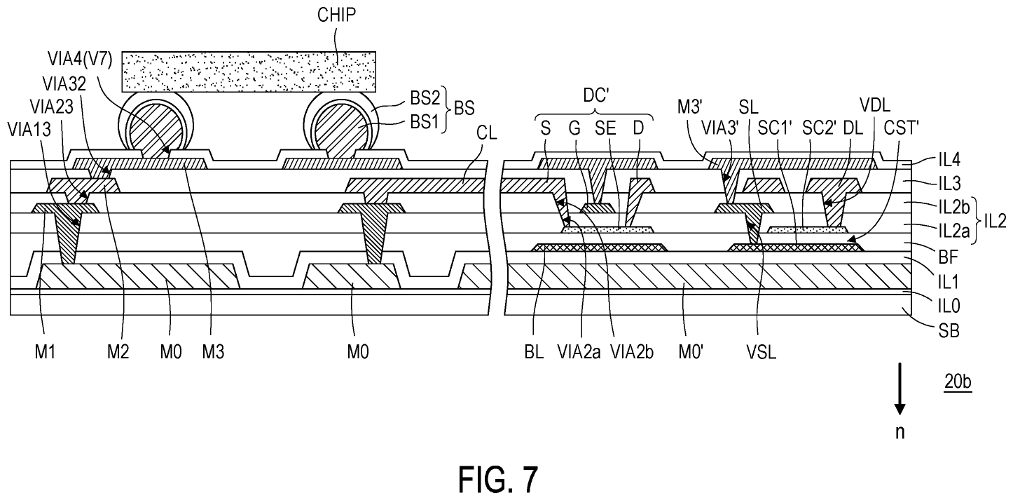

FIG. 7 is a partial cross-sectional schematic view of an electronic device according to a seventh embodiment of the disclosure. It is noted that the embodiment of FIG. 7 may use the reference numerals and a part of the contents of the embodiment of FIG. 6, and the same or similar reference numerals are used to denote the same or similar elements, and the description of the same technical content is omitted.

Referring to FIG. 7, the main difference between the electronic device 20b of this embodiment and the aforementioned electronic device 20a is that the electronic device 20b further includes a conductive layer M3′, in which the conductive layer M3′ and the conductive layer M3 belong to the same layer.

In this embodiment, the scan line SL may be electrically connected to the conductive layer M3′ through the via VIA3′ penetrating the insulating layer IL2b and the insulating layer IL3. Since the conductive layer M3′ is disposed farther away from the conductive layer M0′ than the scan line SL, the distance between the scan line SL and the conductive layer M0′ may be increased by electrically connecting the scan line SL to the conductive layer M3′, thereby the capacitive load generated by the scan line SL may be reduced (the capacitive load is inversely proportional to the distance between the two conductive layers), and the signal transmission quality of the electronic device 20b may be improved. Furthermore, by electrically connecting the scan line SL to the conductive layer M3′, the cross-sectional area of the scan line SL may be increased, thereby reducing the impedance generated by the scan line SL (the impedance value is inversely proportional to the cross-sectional area of the conductive layer). Thus, the signal transmission quality of the electronic device 20b may be improved.

In general, through the design of electrically connecting the scan line SL to the conductive layer M3′, the resistance-capacitance loading of the electronic device 20b may be reduced, and the signal transmission quality of the electronic device 20b may be improved. In addition, in this embodiment, the gate G is also electrically connected to the conductive layer M3′, which may also reduce the resistance-capacitance loading of the electronic device 20b.

It is worth noting that, although not shown in the drawings, other embodiments of the disclosure may also electrically connect the data line DL to the conductive layer M3′, which may also reduce the resistance-capacitance loading of the electronic device 20b.

Based on this, in this embodiment, the chip CHIP is electrically connected to the conductive layer M0 that serves as a pad portion through (1) the via V7, (2) the conductive layer M1 (the conductive layer M1 is connected to the conductive layer M0 through another via VIA13 that is not connected to the via V7) disposed between the insulating layer IL1 and the insulating layer IL2b, (3) the conductive layer M2 (the conductive layer M2 is connected to the conductive layer M1 through another via VIA23 that is not connected to the via V7) disposed between the insulating layer IL2 and the insulating layer IL3, and (4) the conductive layer M3 (the conductive layer M3 is connected to the conductive layer M2 through another via VIA32 that is not connected to the via V7) disposed between the insulating layer IL3 and the insulating layer IL4. Through the design of a conductive layer M1, a conductive layer M2, and a conductive layer M3 disposed between the conductive layer M0 and the chip CHIP, the conductive layer M1, the conductive layer M2, and/or the conductive layer M3 may be electrically connected to the conductive layer M0 and the chip CHIP through different vias for the purpose of connection transition. Therefore, the number of insulating layers penetrated by the via V7 may be relatively reduced, thereby reducing the possibility of defects in the via V7, so that the reliability of the electronic device 20b of this embodiment is improved.

According to the above, in some embodiments of the disclosure, at least one conductive layer is disposed between the pad portion and the chip. The at least one conductive layer may each be electrically connected to the pad portion and the chip through at least one different via for the purpose of connection transition. Therefore, the number of insulating layers penetrated by the at least one via may be relatively reduced, thereby reducing the possibility of defects in the formed via, so that the reliability of the electronic device of the disclosure is improved.

In addition, in other embodiments of the disclosure, by electrically connecting the scan line to the conductive layer above them, since the conductive layer is farther away from the conductive layer such as the ground plate than the scan line, the resistance-capacitance loading of the electronic device of the disclosure may be reduced, and the signal transmission quality of the electronic device of the disclosure may be improved.

Finally, it should be noted that the foregoing embodiments are only used to illustrate the technical solutions of the disclosure, but not to limit the disclosure; although the disclosure has been described in detail with reference to the foregoing embodiments, persons of ordinary skill in the art should understand that the technical solutions described in the foregoing embodiments may still be modified, or parts or all of the technical features thereof may be equivalently replaced; however, these modifications or substitutions do not deviate the essence of the corresponding technical solutions from the scope of the technical solutions of the embodiments of the disclosure. As long as the features of the various embodiments do not violate the spirit of the disclosure or conflict with one another, they may be mixed and matched arbitrarily.

What is claimed is:

1. An electronic device, comprising:
a substrate;
a first conductive layer, disposed on the substrate;
a first insulating layer, disposed on the first conductive layer;
a second conductive layer, disposed on the first insulating layer, wherein the second conductive layer is electrically connected to the first conductive layer;
a second insulating layer, disposed on the second conductive layer and having a second via;
a bonding structure, disposed on the second insulating layer, wherein the bonding structure is electrically connected to the second conductive layer through the second via; and
a chip, disposed on the bonding structure.

2. The electronic device according to claim 1, wherein the first conductive layer is a multi-layer structure.

3. The electronic device according to claim 2, wherein the first conductive layer comprises a copper layer.

4. The electronic device according to claim 1, further comprising:
a third conductive layer, disposed between the first insulating layer and the second conductive layer; and
a third insulating layer, disposed between the third conductive layer and the second conductive layer, and having a third via,
wherein the first insulating layer has a first via, the second conductive layer is electrically connected to the third conductive layer through the third via, and the third conductive layer is electrically connected to the first conductive layer through the first via.

5. The electronic device according to claim 4, further comprising a semiconductor layer disposed between the second conductive layer and the third conductive layer.

6. The electronic device according to claim 1, further comprising:
a third conductive layer, disposed between the first insulating layer and the second conductive layer;
a third insulating layer, disposed between the third conductive layer and the second conductive layer, and having a third via,
a fourth conductive layer, disposed between the third insulating layer and the second conductive layer; and
a fourth insulating layer, disposed between the fourth conductive layer and the second conductive layer, and having a fourth via,
wherein the first insulating layer has a first via, the second conductive layer is electrically connected to the fourth conductive layer through the fourth via, the fourth conductive layer is electrically connected to the third conductive layer through the first via, and the third conductive layer is electrically connected to the first conductive layer through the first via.

7. The electronic device according to claim 6, further comprising:
a semiconductor layer, disposed between the first insulating layer and the fourth conductive layer.

8. The electronic device according to claim 1, wherein the first conductive layer does not overlap with the chip and/or the bonding structure in a top view direction of the substrate.

9. The electronic device according to claim 1, further comprising:
a driving element, disposed on the substrate and comprising a gate, a source, a drain, and a semiconductor layer, wherein the driving element is electrically connected to the chip; and
a storage capacitor, disposed on the substrate and electrically connected to the drain of the driving element,
wherein a material of the semiconductor layer comprises metal oxide or low temperature polysilicon.

10. The electronic device according to claim 9, wherein the second conductive layer comprises a plurality of conductive patterns, wherein at least one of the gate, the source, and the drain is the conductive patterns, and the driving element is located between the first conductive layer and the second conductive layer.

11. The electronic device according to claim 10, further comprising:
a fifth conductive layer, disposed between the second insulating layer and a scan line in a top view direction of the substrate, wherein the scan line and the gate belong to a same layer,
wherein the fifth conductive layer is electrically connected to the scan line.

12. The electronic device according to claim 11, wherein the fifth conductive layer is electrically connected to the gate of the driving element.

13. The electronic device according to claim 9, wherein the driving element partially overlaps the first conductive layer in a top view direction of the substrate.

14. The electronic device according to claim 9, wherein the storage capacitor comprises a first storage electrode and a second storage electrode, wherein the first storage electrode and the gate of the driving element belong to a same layer, and the second storage electrode belongs to a same layer as the source and the drain of the driving element.

15. The electronic device according to claim 14, wherein the first storage electrode is electrically connected to a scan line, and the second storage electrode is electrically connected to a data line.

16. The electronic device according to claim 14, further comprising:
a light shielding layer, disposed between the substrate and a channel region of the semiconductor layer; and
a buffer layer, disposed on the first insulating layer and covers the light shielding layer.

17. The electronic device according to claim 16, wherein the first storage electrode and the light shielding layer belong to a same layer, and the second storage electrode and the semiconductor layer belong to a same layer.

18. The electronic device according to claim 9, further comprising:
a wiring, disposed on the second insulating layer, wherein the wiring is electrically connected to the source of the driving element and the first conductive layer.

19. The electronic device according to claim 1, wherein the chip is a capacitive modulating element.

20. The electronic device according to claim 1, further comprising:
a drive element, wherein the drive element is a circuit chip.
